(19) United States
(12) Patent Application Publication
(10) Pub. No.: US 2011/0123729 A1
(43) Pub. Date: May 26, 2011

(54) DISPLAY SUBSTRATE AND METHOD OF MANUFACTURING THE SAME

(75) Inventors: Sang-Myoung Lee, Hwaseong-si (KR); Tae-Hyung Hwang, Seoul (KR); Jung-Woo Park, Seoul (KR); Kyung-Tae Chae, Hwaseong-si (KR); Hyung-Il Jeon, Incheon (KR); Seok-Joon Hong, Seoul (KR)

(73) Assignee: SAMSUNG ELECTRONICS CO., LTD., Suwon-si (KR)

(21) Appl. No.: 12/917,950

(22) Filed: Nov. 2, 2010

(30) Foreign Application Priority Data
Nov. 24, 2009 (KR) 2009-0113926

(51) Int. Cl. C09K 19/00; B32B 37/02; C23C 14/34

(52) U.S. Cl. 428/1.6; 156/60; 204/192.15

(57) ABSTRACT

A display substrate includes a gate line disposed on a substrate, a data line crossing the gate line, a thin-film transistor electrically connected to the gate line and the data line, a light blocking layer disposed on the substrate and the thin-film transistor, where the light blocking layer blocks light and includes at least one selected from the group consisting of a zinc oxide, a copper oxide and a zinc-copper-oxide composite, and a pixel electrode electrically connected to the thin-film transistor.

This application claims priority to Korean Patent Applications No. 2009-0113926, filed on Nov. 24, 2009, and all the benefits accruing therefrom under 35 U.S.C. §119, the content of which in its entirety is herein incorporated by reference.

### BACKGROUND OF THE INVENTION

1. Field of the Invention

Exemplary embodiments of the present invention relate to a display substrate and a method of manufacturing the display substrate. More particularly, exemplary embodiments of the present invention relate to a display substrate with improved display quality and a method of manufacturing the display substrate.

2. Description of the Related Art

In general, a liquid crystal display (“LCD”) device includes a display substrate (also referred to as “an array substrate”) having a switching element such as a thin-film transistor and an opposing substrate facing the display substrate and combining with the display substrate, thereby forming a receiving space for a liquid crystal layer. A plurality of pixels is typically defined on the display substrate by signal lines, and the switching element is formed in each of the pixels. The opposing substrate includes a plurality of color filters corresponding to the pixels, and a black matrix is formed between the color filters to prevent light leakage between the pixels.

Recently, a color filter on array (“COA”) method for forming a color filter on an array substrate and a black matrix on array (“BOA”) method for forming a black matrix on an array substrate have been developed. According to the COA method or the BOA method, an alignment margin of an array substrate and an opposing substrate is generally not considered, e.g., the extra alignment margin may be effectively eliminated, so that an opening ratio of the pixels is increased. Furthermore, manufacturing costs may be substantially reduced due to a simplified structure of the opposing substrate.

When a metal material is used for the black matrix, a perceptibility of the black matrix may be substantially reduced. Furthermore, when the black matrix includes a carbon black material, the carbon black material may be insufficiently dispersed throughout the black matrix, and therefore a light-blocking ability may be substantially reduced according to dispersion extent of the carbon black. Furthermore, the black matrix including a metal and a carbon black may be conductive, thereby causing undesirable leakage of electric current from a pixel electrode.

### BRIEF SUMMARY OF THE INVENTION

Exemplary embodiments of the present invention provide a display substrate with improved display quality.

Exemplary embodiments of the present invention further provide a method of manufacturing the display substrate.

In one exemplary embodiment, a display substrate includes a gate line disposed on a substrate, a data line crossing the gate line, a thin-film transistor electrically connected to the gate line and the data line, a light blocking layer disposed on the substrate, where the light blocking layer blocks light and comprises at least one selected from the group consisting of a zinc oxide, a copper oxide and a zinc-copper-oxide composite, and a pixel electrode electrically connected to the thin-film transistor.

In one exemplary embodiment, a thickness of the light blocking layer may be in a range of about 1,000 Å to about 1,200 Å.

In one exemplary embodiment, the zinc oxide absorbs light in a wavelength range of about 100 nm to about 370 nm.

In one exemplary embodiment, the copper oxide absorbs light in a wavelength range of about 380 nm to about 770 nm.

In one exemplary embodiment, a method of manufacturing a display substrate includes, providing a thin-film transistor on a substrate, where the thin-film transistor is connected to a gate line and a data line crossing the gate line, providing a light blocking layer on the substrate and the thin-film transistor, where the light blocking layer includes at least one selected from the group consisting of a zinc oxide, a copper oxide and a zinc-copper-oxide composite, and electrically connecting a pixel electrode to the thin-film transistor.

In one exemplary embodiment, providing the light blocking layer may include forming a photo-curable layer including a photo-curable material mixed with a composite particle of a zinc oxide and a copper oxide, and patterning the photo-curable layer to form the light blocking layer on the thin-film transistor.

In one exemplary embodiment, the composite particle may be formed by coating zinc oxide particles on a copper oxide particle, where the copper oxide particle is larger than the zinc oxide particles.

In one exemplary embodiment, the photo-curable material may include an acryl resin.

In one exemplary embodiment, providing the light blocking layer includes depositing a zinc-copper-oxide composite on the substrate at a room temperature through a sputtering process, and patterning the zinc-copper-oxide composite to form the light blocking layer on the thin-film transistor.

In one exemplary embodiment, providing the light blocking layer may further include forming the zinc-copper-oxide composite, where forming the zinc-copper-oxide composite includes mixing zinc oxide particles and copper oxide particles, drying zinc oxide particles and copper oxide particles, and sintering a mixture of the zinc oxide particles and the copper oxide particles.

In one exemplary embodiment, the zinc-copper-oxide composite may include copper oxide and zinc oxide in a weight ratio of about 1:1.5 to about 1:2.33.

In one exemplary embodiment, the deposited zinc-copper-oxide composite may have an amorphous phase.

### BRIEF DESCRIPTION OF THE DRAWINGS

The above and other features and aspects of the present invention will become more apparent by describing in further detailed exemplary embodiments thereof with reference to the accompanying drawings, in which:

FIG. 1 is a top plan view of an exemplary embodiment of a display substrate according to the present invention;

FIG. 2 is a cross-sectional view taken along line I-I′ of FIG. 1;

FIGS. 3A, 3B, 3C, 3D and 3E are cross-sectional views illustrating an exemplary embodiment of a method of manufacturing a display substrate according to the present invention;

FIG. 4 is a graph illustrating absorbance versus wavelength (nm) and showing a UV-block ability of zinc oxide included in an exemplary embodiment of the display substrate;

FIG. 5 is a graph illustrating transmission (%) at 550 nm versus O₂ flow rate (sccm) and showing a visible ray block ability of copper oxide included in an exemplary embodiment of the display substrate; and

FIGS. 6A, 6B, 6C, 6D and 6E are cross-sectional views illustrating an alternative exemplary embodiment of a method of manufacturing a display substrate according to the present invention.

### DETAILED DESCRIPTION OF THE INVENTION

The invention is described more fully hereinafter with reference to the accompanying drawings, in which exemplary embodiments of the invention are shown. The invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, connected may refer to elements being physically and/or electrically connected to each other. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized exemplary embodiments (and intermediate structures) of the invention. As such, variations from the shapes of the illustrations as a result, for example, of manufacturing techniques and/or tolerances, are to be expected. Thus, exemplary embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention is described more fully hereinafter with reference to the accompanying drawings, in which exemplary embodiments of the present invention are shown.

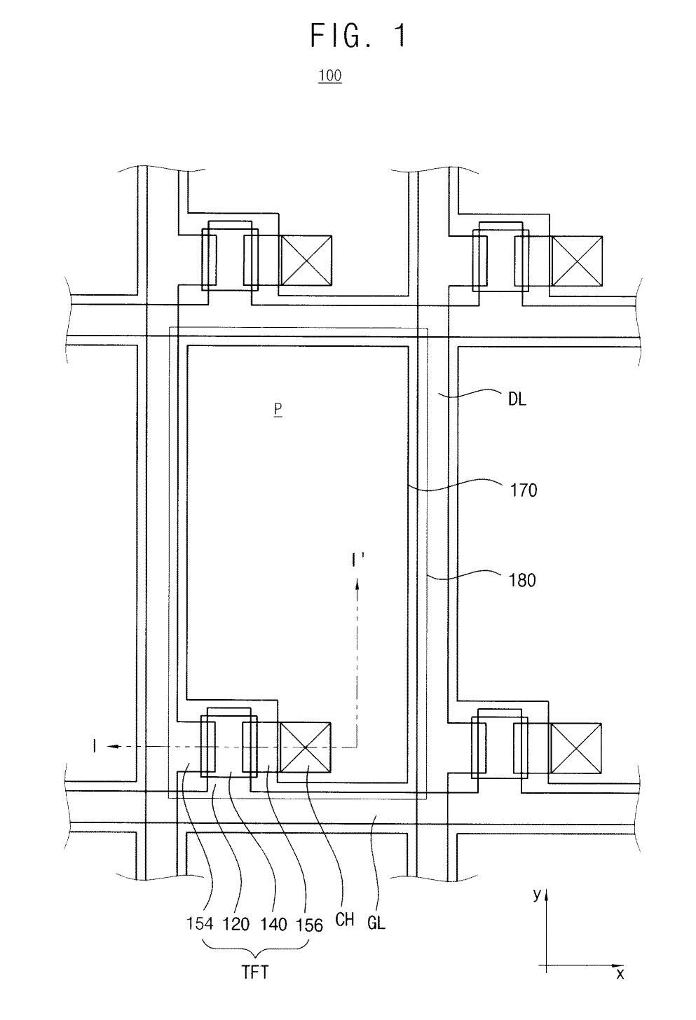

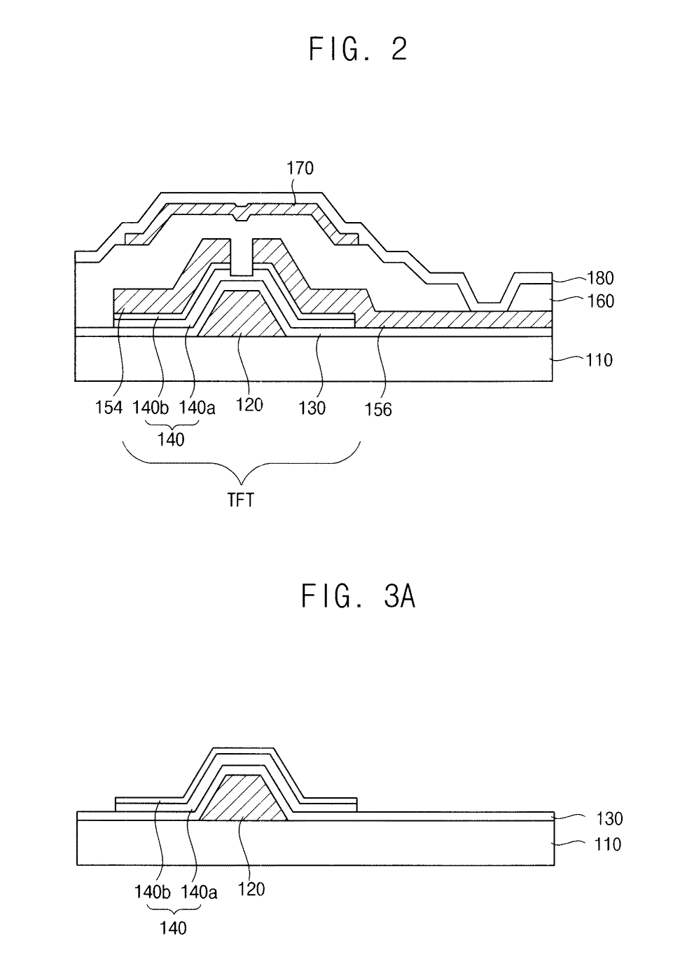

FIG. 1 is a top plan view of an exemplary embodiment of a display substrate according to the present invention. FIG. 2 is a cross-sectional view taken along line I-I′ of FIG. 1.

Referring to FIGS. 1 and 2, an exemplary embodiment of a display substrate 100 includes a substrate 110, a gate line GL, a data line DL, a switching element TFT, a passivation layer 160, a light blocking layer 170 and a pixel electrode 180. In an exemplary embodiment, the switching element TFT may be a thin-film transistor.

The gate line GL extends in a first direction, e.g., an x direction in FIG. 1, and the data line DL extends in a second direction, e.g., a y direction in FIG. 1, crossing the first direction, e.g., the x direction. In an exemplary embodiment, a pixel P is defined by the gate line GL and the data line DL.

The switching element TFT is disposed in the pixel P, and is disposed adjacent to an intersection point of the gate line GL and the data line DL. The switching element TFT applies a pixel voltage to the pixel electrode 180 in response to a scan signal applied to the switching element TFT through the gate line GL, and the pixel voltage is transmitted to the switching element TFT through the data line DL.

The switching element TFT includes a gate electrode 120, a gate insulating layer 130, a source electrode 154, a drain electrode 156 and an active layer 140. The gate electrode 120 extends from the gate line GL. In an exemplary embodiment, the gate line GL may have a double-layered structure of aluminum/molybdenum or titanium/copper.

The gate insulating layer 130 is disposed on the gate electrode 120. In an exemplary embodiment, the gate insulating layer 130 may include a material such as silicon nitride, silicon oxide and the like.

The source electrode 154 extends from the data line DL, and overlaps the gate electrode 120 on the gate insulating layer 130. In an exemplary embodiment, the data line DL may have a double-layered structure of titanium/copper. In an alternative exemplary embodiment, the data line DL may have a triple-layered structure of molybdenum/aluminum/molybdenum.

The drain electrode 156 is spaced apart from the source electrode 154 by a predetermined distance, and overlaps at least a portion of the gate electrode 120 on the gate insulating layer 130.

The active layer 140 is disposed between the source electrode 154 and the gate insulating layer 130 and between the drain electrode 156 and the gate insulating layer 130. The active layer 140 may have a shape substantially the same as the shape of the source electrode 154 and the drain electrode 156 in a top plan view. The active layer 140 includes an amorphous silicon (“a-Si:H”) layer 140a and an n+ amorphous silicon (“n+ a-Si:H”) layer 140b disposed on the amorphous silicon layer 140a. The source electrode 154 and the drain electrode 156 are electrically connected to the active layer 140. An electrical channel is form in the active layer 140 by a scan signal applied through the gate line GL, and a pixel voltage transmitted through the date line DL is thereby applied to the pixel electrode 180 through the active layer 140 and the drain electrode 156.

The passivation layer 160 is disposed on the substrate 110 including the switching element TFT covering the switching element TFT. In an exemplary embodiment, the passivation layer 160 may include a material such as silicon nitride, silicon oxide and the like. The passivation layer 160 may be formed through a plasma enhanced chemical vapor deposition (“PECVD”) process. A contact hole CH is formed through the passivation layer 160, and the contact hole CH exposes at least a portion of the drain electrode 156.

The light blocking layer 170 is disposed on the passivation layer 160 overlapping the switching element TFT. The light blocking layer 170 is further disposed on the passivation layer 160 overlapping the gate line GL and the data line DL. A thickness of the light blocking layer 170 is in a range of about 1,000 Å to about 1,200 Å.

In an exemplary embodiment, the light blocking layer 170 includes zinc oxide (ZnO) and copper oxide (CuO). The light blocking layer 170 further includes a photosensitive organic composition, such as a photo-curable acryl binder resin, for example. The zinc oxide absorbs light in a wavelength range of about 100 nm to about 370 nm. The copper oxide absorbs light in a wavelength range of about 380 nm to about 770 nm. Therefore, the light blocking layer 170 disposed on the substrate 110 may effectively prevent light from leaking downwardly. Furthermore, the light blocking layer 170 blocks both of an infrared ray and an ultraviolet ray, and a display quality is thereby substantially improved.

The pixel electrode 180 is disposed on the passivation layer 160 and corresponding to the pixel P. The pixel electrode 180 includes a transparent conductive material which transmits light. In an exemplary embodiment, the transparent conductive material may include indium zinc oxide (“IZO”), indium tin oxide (“ITO”), and the like, but not being limited thereto. The pixel electrode 180 is in contact with the drain electrode 156 through the contact hole CH, and receives the pixel voltage through the drain electrode 156.

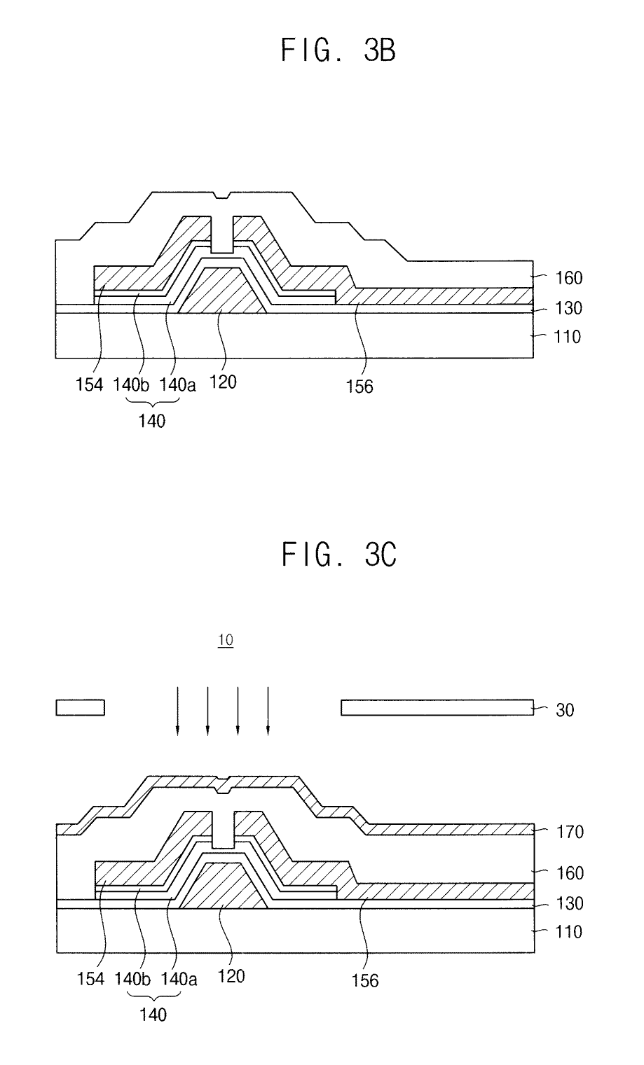

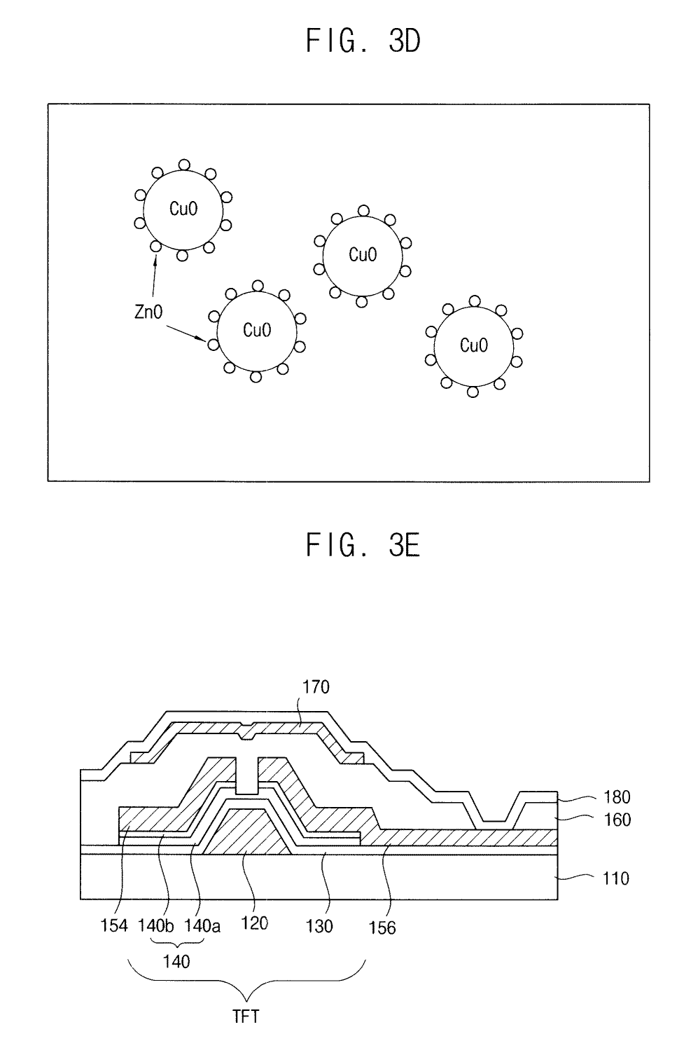

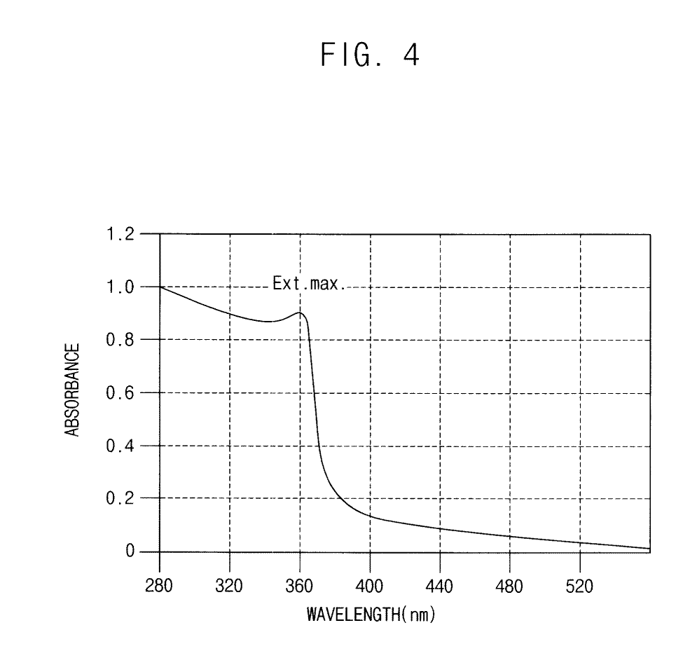

FIGS. 3A, 3B, 3C, 3D and 3E are cross-sectional views illustrating an exemplary embodiment of a method of manufacturing a display substrate according to the present invention.

Referring to FIG. 3A, a metal layer is deposited on a substrate 110, and patterned through a photolithography process to form a gate line GL and a gate electrode 120. In an exemplary embodiment, the metal layer may have a double-layered structure including an aluminum layer and a molybdenum layer. The gate line GL extends in a first direction, e.g., the x direction (FIG. 1), and the gate electrode 120 protrudes from the gate line GL.

In an exemplary embodiment, the gate insulating layer 130, including a material such as silicon nitride or silicon oxide, for example, is formed on the substrate 110 and the gate electrode 120 through a PECVD process.

In an exemplary embodiment, the amorphous silicon layer 140a is formed on the gate insulating layer 130 through a sputtering method using a silicon target. The sputtering method may be performed at a temperature lower than about 100° C., while the PECVD process may be performed at a temperature of about 300° C. to about 400° C.

In an exemplary embodiment, an ohmic contact layer 140b is formed on the amorphous silicon layer 140a through a PECVD process. The ohmic contact layer 140b includes ion-implanted amorphous silicon layer. In an exemplary embodiment, n-type ions or p-type ions may be implanted into an amorphous silicon layer to form the ohmic contact layer 140b. Accordingly, the active layer 140 including the amorphous silicon layer 140a and the ohmic contact layer 140b formed on the amorphous silicon layer 140a is formed.

Referring to FIG. 3B, a metal layer is deposited on the gate insulating layer 130 after the active layer 140 is formed. In an exemplary embodiment, the metal layer is formed through a sputtering method. In an exemplary embodiment, the metal layer may have a triple-layered structure including an upper molybdenum layer, an aluminum layer and a lower molybdenum layer. The metal layer, the amorphous silicon layer 140a and the ohmic contact layer 140b are patterned through a photolithography process, a data line DL, a source electrode 154 and a drain electrode 156 are thereby formed.

The data line DL extends in a second direction, e.g., the y direction (FIG. 1), to cross the gate line GL. In an exemplary embodiment, a plurality of data lines crosses a plurality of gate lines. A plurality of pixels P is defined the plurality of data lines and the plurality of gate lines. Therefore, a switching element TFT, including the gate electrode 120, the source electrode 154, the drain electrode 156 and the active layer 140, is formed in each of the plurality of pixels P.

A passivation layer 160 is formed on the gate insulating layer 130 after the switching element TFT is formed. In an exemplary embodiment, the passivation layer 160 may include a material such as silicon nitride, silicon oxide and the like, for example, but not being limited thereto. In an exemplary embodiment, the passivation layer 160 may be formed through a PECVD process.

Referring to FIGS. 3C and 3D, a photosensitive organic composition including zinc oxide and copper oxide is formed on the passivation layer 160 to form a light blocking layer 170. In an exemplary embodiment, zinc oxide particles smaller than copper oxide particles may be coated on the copper oxide particles. The copper oxide particles may have a diameter of about 0.1 μm to about 10 μm, and the zinc oxide particles may be nano-sized particles. In an exemplary embodiment, the zinc oxide particles may be coated on the copper oxide particles through a sol-gel method, a precipitation method or a spraying-drying method, for example, but not being limited thereto, and composite particles of zinc oxide and copper oxide are thereby formed, as shown in FIG. 3D.

A photosensitive organic composition, e.g., a photo-curable acryl binder resin, is provided to the composite particles of zinc oxide and copper oxide. The photosensitive organic composition having the photo-curable acryl binder resin and the composite particles of zinc oxide and copper oxide is formed on the substrate and patterned by using a mask to form the light blocking layer 170 that overlaps the switching element TFT.

In an exemplary embodiment, the light blocking layer 170 is formed on the passivation layer 160 overlapping the gate line GL and the data line DL. In an exemplary embodiment, a thickness of the light blocking layer 170 is in a range of about 1,000 Å to about 1,200 Å. The zinc oxide absorbs light in a wavelength range of about 100 nm to about 370 nm. The copper oxide absorbs light in a wavelength range of about 380 nm to about 770 nm.

Referring now to FIG. 3E, the passivation layer 160 is patterned to form a contact hole CH that exposes a portion of the drain electrode 156. Thereafter, a transparent conductive material is coated on the passivation layer 160. In an exemplary embodiment, the transparent conductive material may include IZO, ITO and the like, but not being limited thereto. The transparent conductive material is patterned through a photolithography process to form the pixel electrode 180 corresponding to the pixel P. The pixel electrode 180 is in contact with the drain electrode 156 through the contact hole CH.

FIG. 4 is a graph illustrating absorbance versus wavelength (nm) and showing a UV-block ability of zinc oxide included in an example embodiment of the display substrate. Referring to FIG. 4, the zinc oxide absorbs light having a wavelength of about 100 nm to about 370 nm. Thus, it can be noted that the zinc oxide may efficiently block an ultraviolet (“UV”) ray.

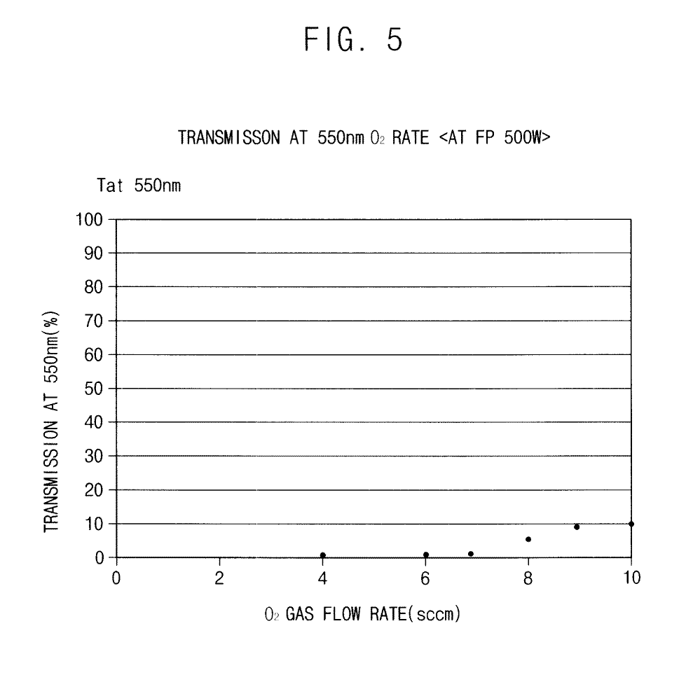

FIG. 5 is a graph illustrating transmission at 550 nm (%) versus O₂ flow rate (sccm) and showing a visible ray block ability of copper oxide included in an exemplary embodiment of the display substrate. More particularly, FIG. 5 shows transmittance of a copper oxide layer to light having a wavelength of about 550 nm, and shows the transmittance varies depending on flow rates (sccm) of oxygen gas in a process of forming the copper oxide layer. Referring to FIG. 5, an absorption ratio of the copper oxide is less than about 10% with respect to a light having a wavelength of 550 nm, which is in the wavelength range of visible lay. As shown in FIG. 5, the copper oxide absorbs light in a wavelength range of about 380 nm to about 770 nm, and the copper oxide is thus efficiently block a visible ray.

In an exemplary embodiment, the display substrate includes the light blocking layer 170 including zinc oxide and copper oxide and formed on the substrate 110, and the zinc oxide absorbs a Ultraviolet (“UV”) ray, and the copper oxide absorbs a visible ray. Accordingly, the light blocking layer 170 may block both of the UV ray and the visible ray, and a display quality is thereby substantially improved.

Hereinafter, an alternative exemplary embodiment of the display substrate will be described. In an alternative exemplary embodiment, the display substrate is substantially the same as the display substrate shown in FIG. 2 except that the light blocking layer includes a zinc-copper-oxide composite. Thus, any repetitive detailed description thereof will hereinafter be omitted or simplified.

In an exemplary embodiment, the display substrate includes a substrate, a gate line, a data line, a switching element, a passivation layer, a light blocking layer and a pixel electrode.

The light blocking layer includes a zinc-copper-oxide composite formed by using zinc oxide and copper oxide. The zinc-copper-oxide composite is formed on the passivation layer through a sputtering process at a room temperature, and the sputtering process uses copper oxide and zinc oxide in a weight ratio of about 1:1.5 to about 1:2.33. The zinc oxide absorbs light in a wavelength range of about 100 nm to about 370 nm. The copper oxide absorbs light in a wavelength range of about 380 nm to about 770 nm. Therefore, the light blocking layer effectively prevents light from leaking downwardly.

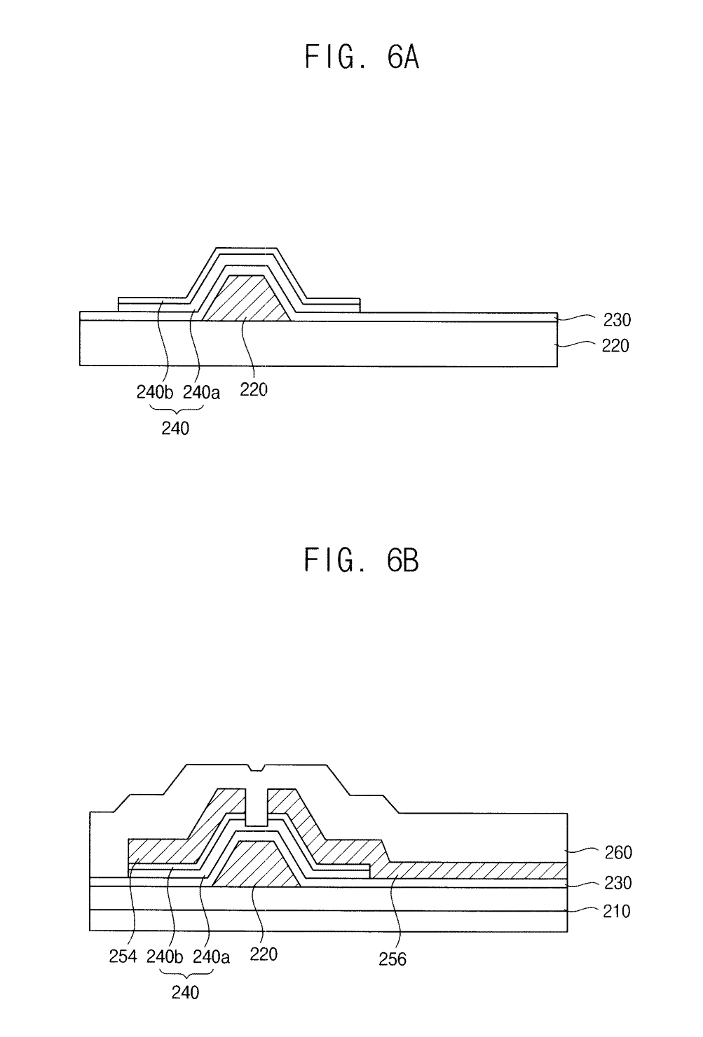

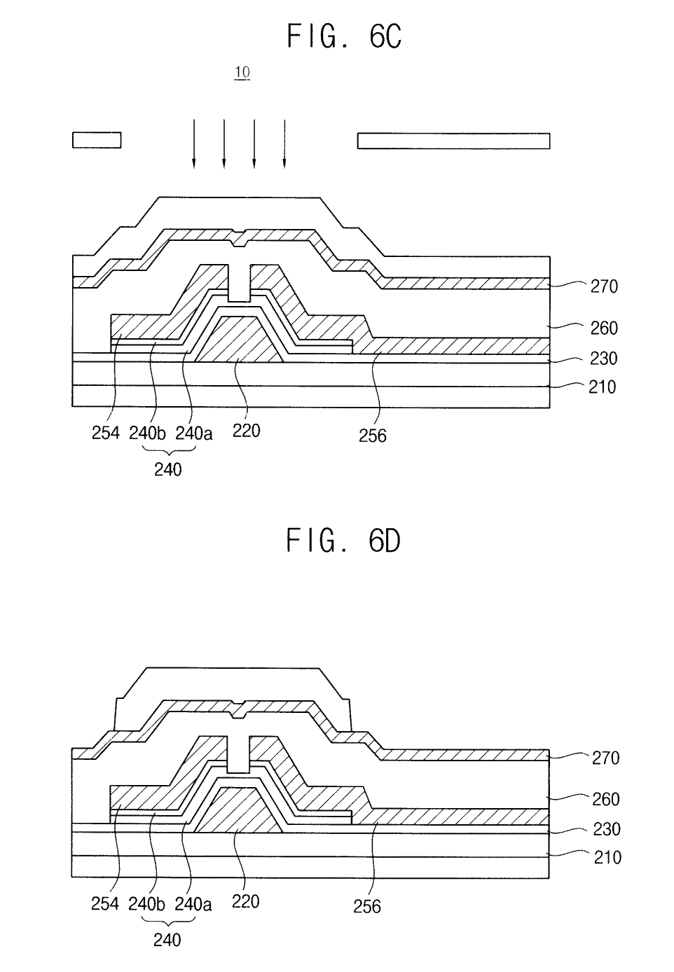

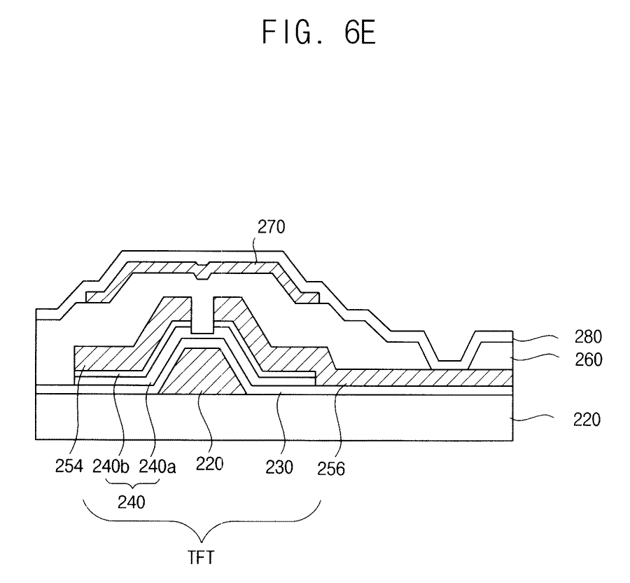

Furthermore, the light blocking layer may block both of the UV ray and the visible ray, and a display quality is thereby substantially improved. FIGS. 6A, 6B, 6C, 6D and 6E are cross-sectional views illustrating an alternative exemplary embodiment of a method of manufacturing a display substrate according to the present invention.

The method of manufacturing a display substrate shown in FIGS. 6A to 6E is substantially the same as the display substrate illustrated in FIGS. 3A to 3E except that a light blocking layer in FIGS. 6C to 6E includes a zinc-copper-oxide composite. Thus, any repetitive detailed description thereof will hereinafter be omitted or simplified.

Referring to FIGS. 6A and 6B, a gate electrode 220, a gate insulating layer 230, an active layer 240, a source electrode 254, a drain electrode 256 and a passivation layer 260 are sequentially formed on a substrate 210.

Referring to FIGS. 6C and 6D, a zinc-copper-oxide composite (e.g., ZnCuO) is deposited on the passivation layer 260 through a sputtering process to form a light blocking layer 270. The zinc-copper-oxide composite includes copper oxide and zinc oxide in a weight ratio of about 1:1.5 to about 1:2.33. In an exemplary embodiment, a zinc-copper-oxide composite is prepared by mixing and drying copper oxide particles and zinc oxide particles and sintering the mixture to form the zinc-copper-oxide composite in the light blocking layer 270.

In an exemplary embodiment, the zinc-copper-oxide composite having an amorphous phase may be deposited on the passivation layer 260 at a room temperature through a sputtering process without a heating process to form a zinc-copper-oxide composite layer. A negative-type photoresist is formed on the zinc-copper-oxide composite layer, and then patterned to form a photoresist pattern. Thereafter, the zinc-copper-oxide composite layer is patterned to form the light blocking layer 270 that overlaps the switching element TFT.

Furthermore, the light blocking layer 270 is formed on the passivation layer 260 overlapping the gate line GL and the data line DL. In an exemplary embodiment, a thickness of the light blocking layer 270 is in a range of about 1,000 Å to about 1,200 Å. The zinc oxide absorbs light in a wavelength range of about 100 nm to about 370 nm. The copper oxide absorbs light in a wavelength range of about 380 nm to about 770 nm.

Referring to FIG. 6E, after the light blocking layer 270 is formed, the passivation layer 260 is patterned to form a contact hole CH that exposes a portion of the drain electrode 256. Thereafter, a transparent conductive material is coated on the passivation layer 260, and then patterned to form a pixel electrode 280 corresponding to the pixel P. The pixel electrode 280 is in contact with the drain electrode 256 through the contact hole CH.

According to exemplary embodiments of the present invention as described herein, a display substrate includes a light blocking layer 270 disposed on a substrate 210 and having a zinc-copper-oxide composite, and a zinc oxide of the zinc-copper-oxide composite absorbs a UV ray, and a copper oxide of the zinc-copper-oxide composite absorbs a visible ray. Accordingly, the light blocking layer 270 blocks both of the UV ray and the visible ray, and a display quality is thereby substantially improved.

While the present invention has been particularly shown and described with reference to exemplary embodiments thereof, it will be understood by those of ordinary skill in the art that various changes in form and details may be made therein without departing from the spirit or scope of the present invention as defined by the following claims.

What is claimed is:

1. A display substrate comprising:
a gate line disposed on a substrate;
a data line crossing the gate line;
a thin-film transistor electrically connected to the gate line and the data line;
a light blocking layer disposed on the substrate and the thin-film transistor, wherein the light blocking layer blocks light and comprises at least one selected from the group consisting of a zinc oxide, a copper oxide and a zinc-copper-oxide composite; and
a pixel electrode electrically connected to the thin-film transistor.

2. The display substrate of claim 1, wherein a thickness of the light blocking layer is in a range of about 1,000 Å to about 1,200 Å.

3. The display substrate of claim 1, wherein the zinc oxide absorbs light in a wavelength range of about 100 nm to about 370 nm.

4. The display substrate of claim 1, wherein the copper oxide absorbs light in a wavelength range of about 380 nm to about 770 nm.

5. A method of manufacturing a display substrate, the method comprising:
providing a thin-film transistor on a substrate, wherein the thin-film transistor is connected to a gate line and a data line crossing the gate line;
providing a light blocking layer on the substrate and the thin-film transistor, wherein the light blocking layer comprises at least one selected from the group consisting of a zinc oxide, a copper oxide and a zinc-copper-oxide composite; and
electrically connecting a pixel electrode to the thin-film transistor.

6. The method of claim 5, wherein providing the light blocking layer comprises:
forming a photo-curable layer including a photo-curable material mixed with a composite particle of a zinc oxide and a copper oxide on the substrate; and
patterning the photo-curable layer to form the light blocking layer on the thin-film transistor.

7. The method of claim 6, wherein the composite particle is formed by coating zinc oxide particles on a copper oxide particle, wherein the copper oxide particle is larger than the zinc oxide particles.

8. The method of claim 6, wherein the photo-curable material includes an acryl resin.

9. The method of claim 5, wherein providing the light blocking layer comprises:
depositing a zinc-copper-oxide composite on the substrate at a room temperature through a sputtering process; and
patterning the zinc-copper-oxide composite to form the light blocking layer on the thin-film transistor.

10. The method of claim 9, wherein providing the light blocking layer further comprises forming the zinc-copper-oxide composite, wherein forming the zinc-copper-oxide composite comprises:
mixing zinc oxide particles and copper oxide particles;
drying the zinc oxide particles and the copper oxide particles; and
sintering a mixture of the zinc oxide particles and the copper oxide particles.

11. The method of claim 10, wherein the zinc-copper-oxide composite includes a copper oxide and a zinc oxide in a weight ratio of about 1:1.5 to about 1:2.33.

12. The method of claim 9, wherein the deposited zinc-copper-oxide composite has an amorphous phase.

13. The method of claim 5, wherein the zinc oxide absorbs light in a wavelength range of about 100 nm to about 370 nm.

14. The method of claim 5, wherein the copper oxide absorbs light in a wavelength range of about 380 nm to about 770 nm.
